(19) United States
(12) Patent Application Publication
(10) Pub. No.: US 2012/0057321 A1
(43) Pub. Date: Mar. 8, 2012

(54) PLASMA DISPLAY DEVICE AND METHOD OF MANUFACTURING THE SAME

(75) Inventor: Jae-woong JUNG, Suwon-si (KR)

(73) Assignee: SAMSUNG ELECTRONICS CO., LTD., Suwon-si (KR)

(21) Appl. No.: 13/197,305

(22) Filed: Aug. 3, 2011

(30) Foreign Application Priority Data
Sep. 2, 2010 (KR) 10-2010-0086145

(51) Int. Cl. H05K 7/04

(52) U.S. Cl. 361/807

(57) ABSTRACT

A plasma display device and a method of manufacturing the same are provided. The plasma display device includes a panel, a driving circuit portion driving the panel, a base chassis on which the driving circuit portion is mounted, and a conductive gasket physically connecting the driving circuit portion to the base chassis. According to the plasma display device, EMI emitted from a driving circuit portion can be shielded, and thus the performance of the plasma display device can be improved.

### CROSS-REFERENCE TO RELATED PATENT APPLICATION

This application claims priority under 35 U.S.C. §119(a) to Korean Patent Application No. 10-2010-0086145, filed on Sep. 2, 2010, in the Korean Intellectual Property Office, the disclosure of which is incorporated herein by reference.

### BACKGROUND

1. Field

Exemplary embodiments relate generally to a plasma display device and a method of manufacturing the same, and more particularly, to a plasma display device and a method of manufacturing the same, which can attenuate EMI noise.

2. Description of the Related Art

Flat display devices have become popular for portable devices, and with the development of large-scale technology in the field of large-scale display devices, CRT (Cathode Ray Tube) display devices have been rapidly replaced by flat display devices.

Among such flat display devices, a plasma display panel (hereinafter referred to as a “PDP”) is a kind of flat display device which displays characters or graphics by light emitted from plasma that is generated during gas discharge. The PDP has a high luminance and light emitting efficiency in comparison to other flat display devices. Also, the PDP has a wide viewing angle, and has been extensively commercialized in recent times.

One of shortcomings of the plasma display panel that is presently pointed out is that large electromagnetic wave noises arise when driving the plasma display device to cause the occurrence of electromagnetic interference (EMI). That is, since a high voltage of about 200V and RMS current of more than 2A are applied to respective electrodes that constitute the plasma display panel, energy of driving waves that produce discharge is radiated as EMI through the electrodes of the panel acting as antennas.

The EMI produces radio noises which may obstruct reception of a desired electromagnetic signal to cause malfunction of electronic appliances. Also, the EMI may be absorbed into a living body in the form of electronic energy to cause a temperature increase in the living body, and thus living organisms and functions may be damaged.

In particular, since the EMI occurs greatly in a driving circuit portion that drives the panel, it causes a deterioration in operations of units positioned near the driving circuit portion. Particularly, in the case where an infrared receiving unit for receiving an infrared signal from an external remote controller is influenced by the EMI, the infrared receiving rate is considerably reduced, and it becomes difficult to control the PDP through the remote controller unless a user is positioned very close to the infrared receiving unit. To prevent this, a bracket may be used to shield the EMI in the panel. However, since a thin PDP is required, there is a need for another method for shielding the EMI in the case where such a bracket is removed.

### SUMMARY

The present disclosure has been made to address at least the above problems and/or disadvantages and to provide at least the advantages described below. Accordingly, exemplary embodiments may provide a plasma display device and a method of manufacturing the same, which can shield EMI emitted from a driving circuit portion.

According to one exemplary embodiment, a plasma display device includes a panel; a driving circuit portion driving the panel; a base chassis on which the driving circuit portion is mounted; and a conductive gasket physically connecting the driving circuit portion to the base chassis.

The conductive gasket may physically connect and fix the driving circuit portion to edge portions of the base chassis.

The conductive gasket may physically connect and fix the driving circuit portion to edge portions of the panel together with the edge portions of the base chassis.

The conductive gasket may fix and physically connect only edge portions of a structure in which the panel, the base chassis, and the driving circuit portion are laminated in the form of surrounding the edge portions.

The conductive gasket may physically connect at least one edge portion of upper, lower, left, and right edge portions of the base chassis.

The plasma display device according to an exemplary embodiment may further include a receiving unit wirelessly receiving an external signal; wherein the external signal may be an IR signal or an RF signal output from a remote controller.

Also, the plasma display device according to an exemplary embodiment may further include a back cover shielding the base chassis, the driving circuit portion, and a plurality of units connected to the driving circuit portion.

According to another exemplary embodiment, a method of manufacturing a plasma display device includes attaching a panel to one surface of a base chassis; mounting a driving circuit portion driving the panel on the other surface of the base chassis; and physically connecting the driving circuit portion to the base chassis through a conductive gasket.

The connection step may physically connect and fix the driving circuit portion to edge portions of the base chassis through the conductive gasket.

The connection step may physically connect and fix the driving circuit portion to edge portions of the panel together with the edge portions of the base chassis through the conductive gasket.

The connection step may fix and physically connect only edge portions of a structure in which the panel, the base chassis, and the driving circuit portion are laminated in the form of surrounding the edge portions through the conductive gasket.

The connection step may physically connect at least one edge portion of upper, lower, left, and right edge portions of the base chassis through the conductive gasket.

The method of manufacturing a plasma display device according to an aspect of the present invention may further include forming a receiving unit wirelessly receiving an external signal; wherein the external signal may be an IR signal or an RF signal output from a remote controller.

Also, the method of manufacturing a plasma display device according to an aspect of the present invention may further include attaching a back cover shielding the base chassis, the driving circuit portion, and a plurality of units connected to the driving circuit portion.

### BRIEF DESCRIPTION OF THE DRAWINGS

The above and other aspects, features and advantages of the present disclosure will be more apparent from the following detailed description when taken in conjunction with the accompanying drawings, in which:

FIG. 1 is a diagram illustrating the configuration of a plasma display device according to an exemplary embodiment;

FIG. 2 is a diagram illustrating a basic driving system of a plasma display device according to an exemplary embodiment;

FIG. 3 is a view illustrating the configuration of a plasma display device according to an exemplary embodiment;

FIG. 4 is a view illustrating the configuration of a plasma display device according to another exemplary embodiment;

FIG. 5 is a view illustrating the configuration of a plasma display device according to an exemplary embodiment;

FIG. 6 is a graph illustrating the effects of a plasma display device according to an exemplary embodiment;

FIGS. 7A and 7B are tables representing the effects of a plasma display device according to an exemplary embodiment;

FIGS. 8A and 8B are graphs comparing EMI noises of a plasma display device according to an exemplary embodiment;

FIG. 9 is a flowchart illustrating a method of manufacturing a plasma display device according to an exemplary embodiment;

FIG. 10 is a flowchart illustrating a method of manufacturing a plasma display device according to another exemplary embodiment; and

FIGS. 11A to 11C are views illustrating the configuration of a plasma display device explaining a method of manufacturing the plasma display device according to an exemplary embodiment.

### DETAILED DESCRIPTION

Exemplary embodiments of the present invention are described in detail with reference to the accompanying drawings.

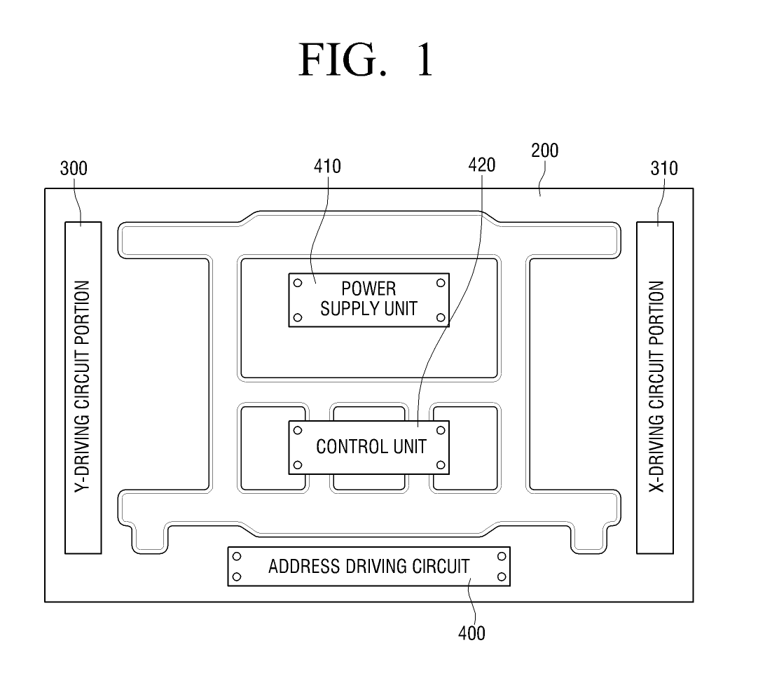

FIG. 1 is a diagram illustrating the configuration of a plasma display device including a base chassis and a driving circuit portion according to an embodiment of the present invention. As illustrated in FIG. 1, driving circuit portions 300, 310, and 400 are mounted on a base chassis 200. The driving circuit portions 300, 310, and 400 are an X-driving circuit portion 310, a Y-driving circuit portion 300, and an address driving circuit portion 400. In addition, a power supply unit 410 and a control unit 420 are mounted on the base chassis 200.

The power supply unit 410 supplies power to the X-driving circuit portion 310, the Y-driving circuit portion 300, the address driving circuit portion 400, and the control unit 420.

The control unit 420 transfers an X-electrode driving control signal, a Y-electrode driving control signal, and an address driving control signal to the X-driving circuit portion 310, the Y-driving circuit portion 300, and the address driving circuit portion 400, respectively, so that the X-driving circuit portion 310, the Y-driving circuit portion 300, and the address driving circuit portion 400 can drive a panel (not illustrated).

Particularly, in the structure of FIG. 1, since high current flows through the X-driving circuit portion 310 and the Y-drive circuit portion 300, which are mounted on the edge surface of the base chassis 200, a large amount of electromagnetic wave noise is radiated to cause a large amount of electromagnetic interference (EMI). A scheme for attenuating the EMI will be described in detail later.

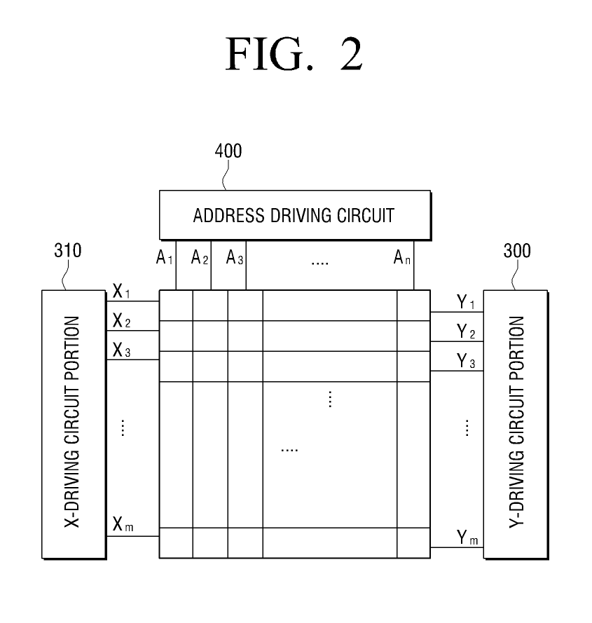

Hereinafter, a method of driving a plasma display device through the X-driving circuit portion 310, the Y-driving circuit portion 300, and the address driving circuit portion 400 will be described with reference to FIG. 2.

FIG. 2 is a diagram illustrating a basic driving system of a plasma display device according to an exemplary embodiment. The X-driving circuit portion 310 is connected to an X electrode of bus electrodes, and drives the panel (not illustrated) based on an X-electrode driving control signal that is received from the control unit 420, and a Y-driving circuit portion 300 is connected to a Y electrode of bus electrodes, and drives the panel (not illustrated) based on a Y-electrode driving control signal that is received from the control unit 420.

The X-driving circuit portion 310 receives the X-electrode driving control signal from the control unit 420, and applies a driving voltage to the X electrode. The Y-driving circuit portion 300 receives the Y-electrode driving control signal from the control unit 420, and applies a driving voltage to the Y electrode. In particular, the X-driving circuit portion 310 and the Y-driving circuit portion 300 performs a maintenance discharge with respect to selected pixels by alternately inputting a sustain voltage to the X electrode and the Y electrode.

The address driving circuit 400 applies a data signal for selecting pixels to be displayed to an address electrode. The bus electrode (X electrode and Y electrode) and the address electrode are formed to cross each other at right angles as illustrated in FIG. 2, and the X electrode and the Y electrode are arranged to face each other, being apart for a discharge space from each other. In this case, the discharge space, which is positioned in the crossing portion of the address electrode, the X electrode, and the Y electrode, forms a discharge cell.

On the other hand, the panel has a structure in which plural pixels are arranged in the form of a matrix, and on each pixel, the X electrode, the Y electrode, and the address electrode are formed. Accordingly, a voltage is applied to the respective electrodes of the panel, and the panel is driven in an ADS (Address Display Separate) driving method. The ADS driving method is a method in which respective sub-fields of the panel are driven as they are separated into a reset section, an address section, and a maintenance discharge section.

The reset section serves to erase the previous wall charge state and to set up wall charge in order to stably perform the next address discharge. The address section is a section in which lighted cells and unlighted cells are selected in the panel and the wall charge is accumulated on the lighted cells (addressed cells). The maintenance discharge section is a section in which discharge for actually displaying an image is performed on the addressed cells by alternately applying a sustain voltage to the X electrode and the Y electrode.

As described above, the panel is driven in such a manner that the discharge is generated using a difference between a voltage applied to the X electrode and a voltage applied to the Y electrode and the panel is illuminated through plasma generation by the discharge.

The operation method or configuration that can be applied to the plasma display device as described above are merely exemplary, and it will be apparent to those of ordinary skill in the art that the scope of the present invention is not limited to those as described above, and the operation method and configuration may be modified and replaced in diverse forms. Particularly, detailed descriptions of constructions or processes known in the art may be omitted to avoid obscuring the subject matter of the present invention.

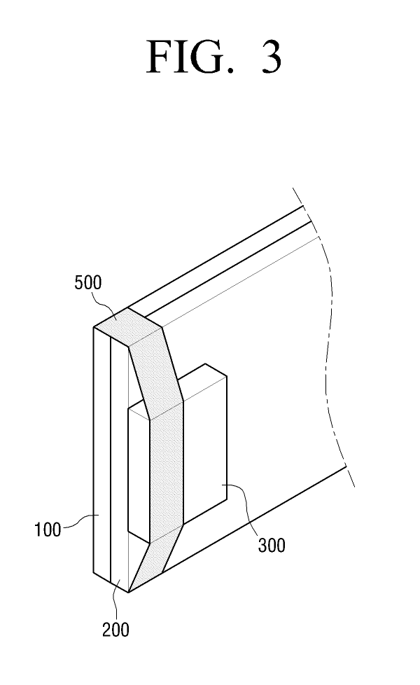

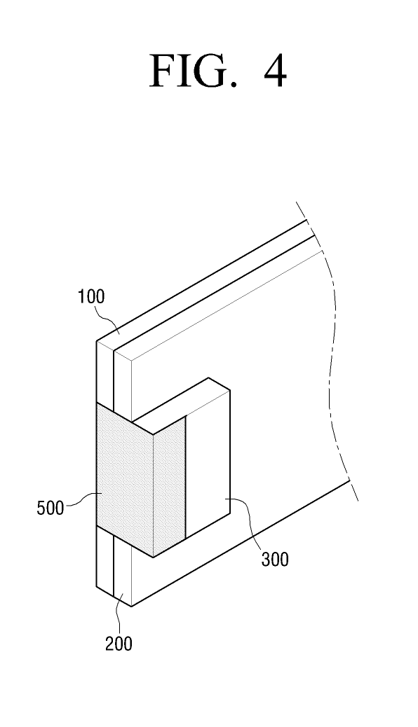

FIGS. 3 and 4 illustrate the configuration of a plasma display device according to an exemplary embodiment. In FIGS. 3 and 4, the configuration of the plasma display device is greatly simplified. Specifically, the power supply unit 410, the address driving circuit portion 400, and the control unit 420 as illustrated in FIG. 1 are omitted, and an edge portion of the Y-driving circuit portion 300 is mainly illustrated in FIGS. 3 and 4.

As illustrated in FIG. 3, on one side of the base chassis 200, the panel 100 is positioned, and on the other side of the base chassis 200, the driving circuit portion 300 is mounted. A gasket or the like may be included in the panel 100 and the base chassis 200, but in FIG. 3, the gasket is omitted for convenience in explanation.

As described above, since the driving circuit portion 300 is driven by high current, it is greatly affected by the EMI. In particular, since the X-driving circuit portion 310 and the Y-driving circuit portion 300 alternately apply the sustain voltage to the X electrode and the Y electrode to cause the maintenance discharge with respect to the selected pixels, the EMI caused by the current has a great effect on the functions of other units put in the neighborhood of the driving circuit unit 300.

For example, a receiving unit (not illustrated) for receiving an infrared signal, which is positioned near the driving circuit portion 300, is affected by the EMI, and the receiving rate is greatly lowered.

Accordingly, as illustrated in FIG. 3, in the case of physically connecting and fixing the driving circuit portion 300, the base chassis 200, and the panel 100 through the conduction gasket 500, the conductive gasket 500 guides the high current that flows through the driving circuit portion 300 to the base chassis 200 that is ground, and thus the EMI that is generated in the driving circuit portion 300 and the edge of the base chassis 400 can be remarkably reduced.

However, unlike FIG. 3, a configuration in which only the base chassis 200 and the driving circuit portion 300, except for the panel 400, are connected through the conductive gasket 500 may be presented. In addition, although the driving circuit portion 300, specifically, only the Y-driving circuit portion 300 is illustrated in FIG. 3, the other edge portion of the base chassis 200, on which the X-driving circuit portion 310 is positioned, the lower edge portion of the base chassis 200, on which the address driving circuit portion 400 is positioned, and the upper edge portion of the base chassis 200 may also be connected through the conductive gasket 500.

FIG. 4 illustrates the physical connection by the conductive gasket 500, which is configured to be different from that in FIG. 3. As illustrated in FIG. 4, the conductive gasket 500 may connect the panel 100, the base chassis 200, and the driving circuit portion 300 in the form of surrounding the edge portions of the panel 100, the base chassis 200, and the driving circuit portion 300. According to this configuration, the effect of attenuating the EMI radiated from the edge portion can be heightened. That is, the EMI itself is prevented from being radiated through the conductive gasket 500 in addition to the adjustment of current flow to the driving circuit portion 300, and thus the effect of the EMI can be further reduced.

It is possible to physically connect and fix only the base chassis 200 and the driving circuit unit 300 except for the panel 100, and it is also possible to connect the Y-driving circuit unit 300, the other side of the base chassis 200, that is, the edge portion on which the X-driving circuit portion 310 is positioned, and the upper edge portion of the base chassis 200 or the lower edge portion of the base chassis 200 on which the address driving circuit portion 400 in a method as illustrated in FIG. 4.

However, the method which can control current in the driving circuit portion 300 is not limited to the method as illustrated in FIGS. 3 and 4. The base chassis 200 and the driving circuit portion 300 may be physically connected in another method using the conductive gasket 500, or the panel 100, the base chassis 200, and the driving circuit portion 300 may be physically connected. Also, in the case where the base chassis 200 and the driving circuit portions 300 and 310 are arranged in a different manner from that as illustrated in the drawings, the configuration of the conductive gasket 500 may be different. A person of ordinary skill in the art can make the conductive gasket 500 in diverse forms to achieve the same effect as that according to the present invention.

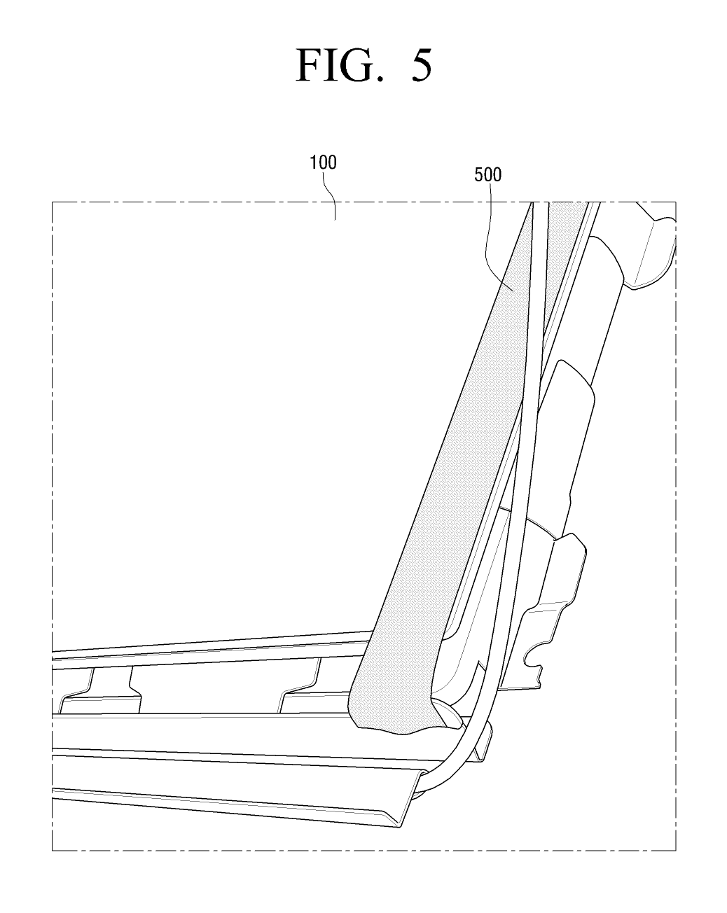

To assist in understanding the present invention, an example of the configuration of the conductive gasket 500 is illustrated in FIG. 5. Unlike FIGS. 3 and 4, FIG. 5 is a view seen from the side of the panel 100. The conductive gasket 500 includes the edge portion of the panel 100, and physically connects the base chassis 200 and the driving circuit portion 300.

Also, as described above, the conductive gasket 500 may be configured as illustrated in FIG. 5, even on the left edge portion of the panel rather than the right edge portion thereof, the upper edge portion, and the lower edge portion.

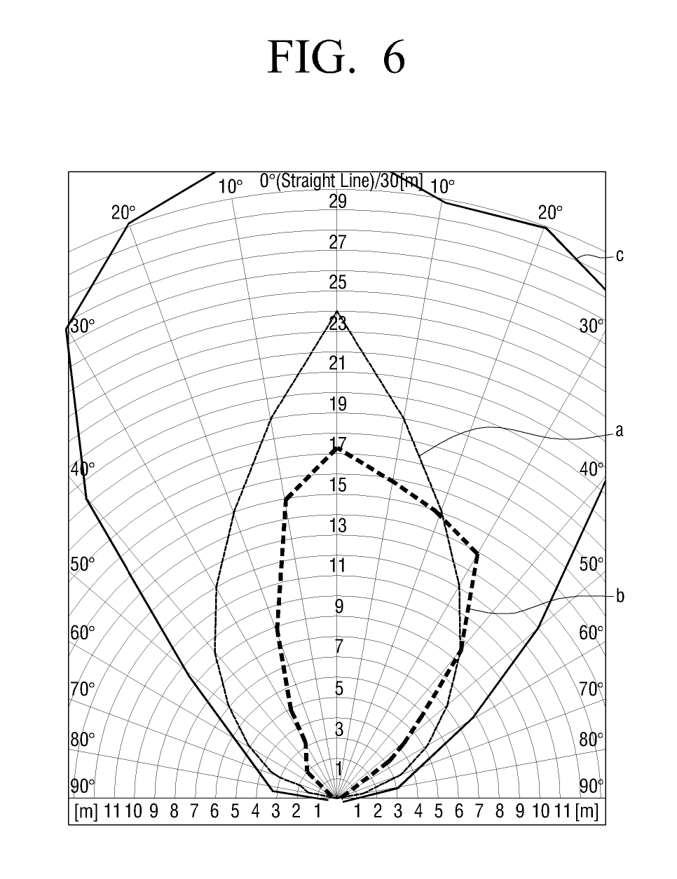

FIG. 6 is a graph illustrating the effects of a plasma display device according to an exemplary embodiment. As shown in FIG. 6, a superior effect can be obtained in the case where the driving circuit portion 300 is connected to the base chassis and/or the panel 100 through the conduction gasket 500.

The graph of FIG. 6 represents infrared signal detection distances according to the EMI in the infrared receiving unit receiving the infrared signal of the remote controller. The reference numeral “a” in FIG. 6 indicates an appropriate standard for the infrared signal detection distance that is generally required in a plasma display device, and defines a distance to the extent that it does not cause a user inconvenience. The reference numeral “b” in FIG. 6 indicates an infrared signal detection distance in the case where the infrared signal is affected by the EMI. Since the infrared signal is greatly affected by the EMI, the infrared signal detection distance is greatly reduced. In this case, it becomes difficult for a user to control the PDP through the remote controller unless the user is positioned very close to the plasma display device.

However, in the case where the driving circuit portion 300 is connected to the base chassis 200 and/or panel 100 through the conductive gasket 500 as in the plasma display device according to an exemplary embodiment, as illustrated as “c” in FIG. 6, it becomes possible to detect the infrared signal farther over the appropriate standard of the infrared signal detection distance. This means that the EMI has been considerably attenuated.

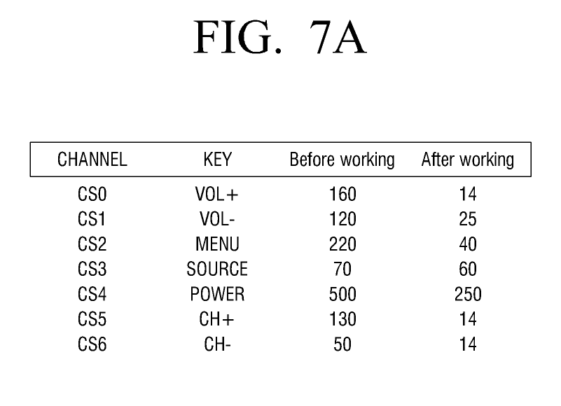

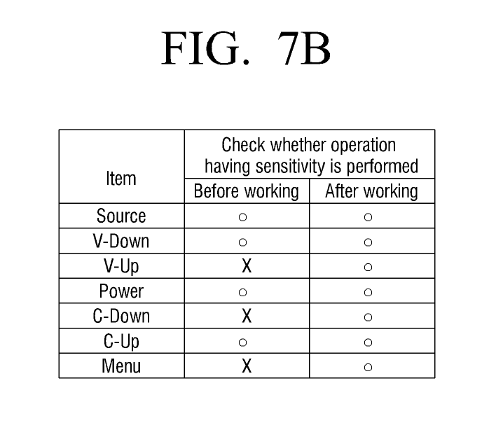

FIGS. 7A and 7B also show the effect of the plasma display device according to an exemplary embodiment. FIG. 7A shows a table representing noises in the infrared receiving unit in the case where the infrared signal from an external remote controller is transferred to the infrared receiving unit. Referring to the table of FIG. 7A, it can be understood that the noise in the infrared receiving unit, which is included in the plasma display device (after working) having the conductive gasket 500, is considerably lower than the noise in the infrared receiving unit, which is included in the plasma display device (before working) having no conductive gasket 500.

Also, FIG. 7B shows a table representing the sensitivity of the infrared receiving unit. It can be understood from FIG. 7B, that the channel region that can be sensed by the plasma display device (after working) having the conductive gasket 500 is considerably wider than the channel region that can be sensed by the plasma display device (before working) having no conductive gasket 500.

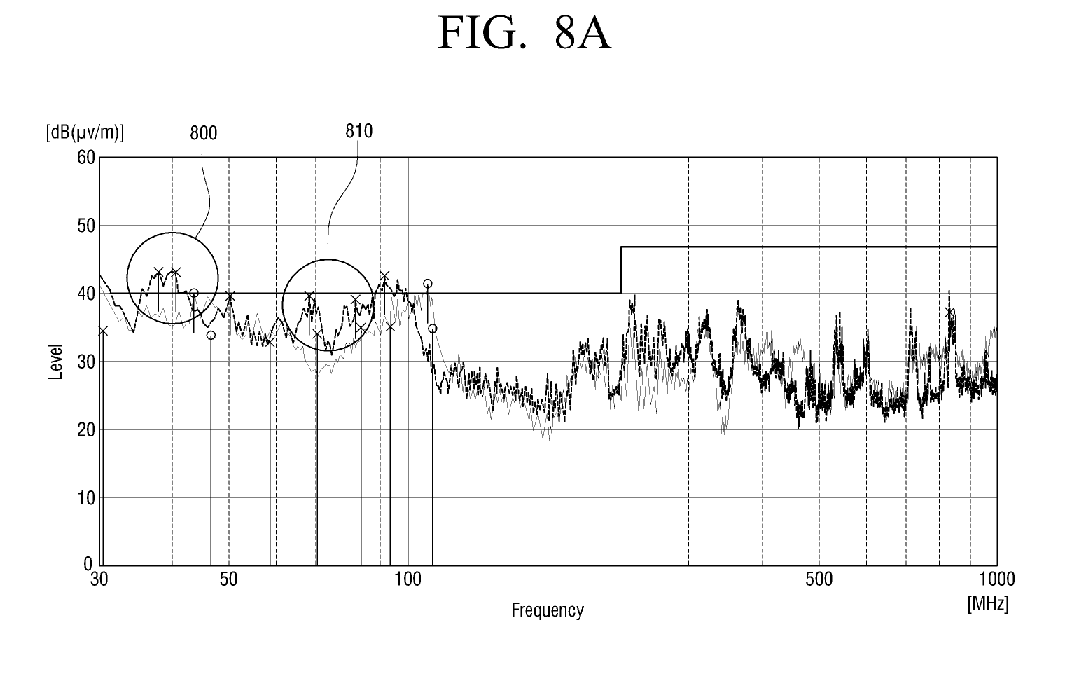

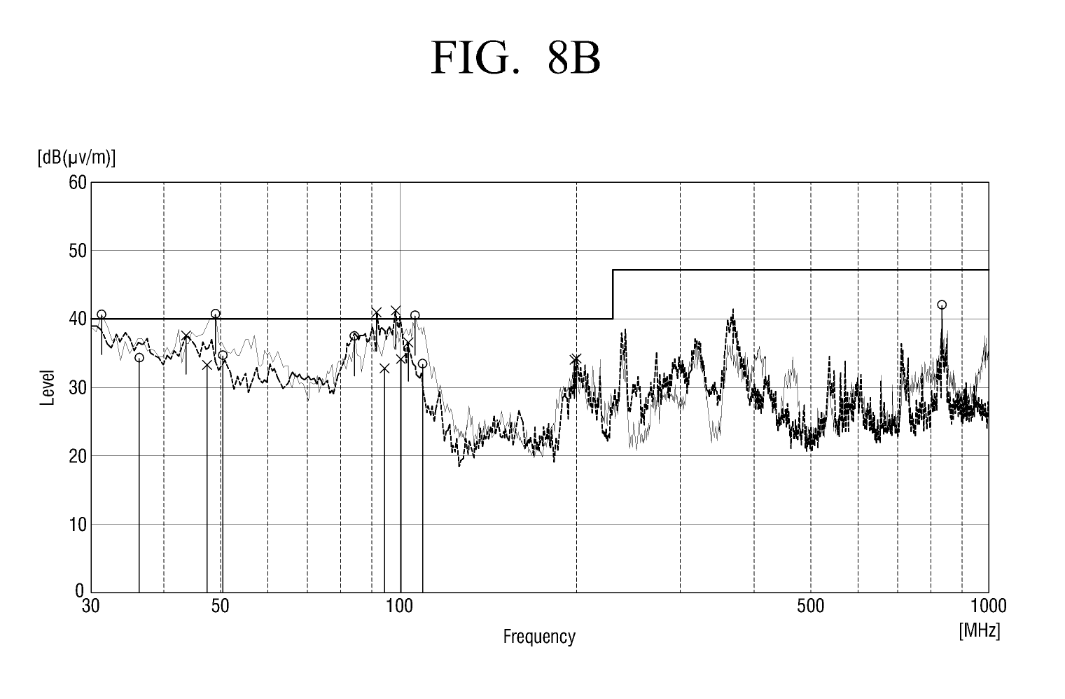

On the other hand, FIGS. 8A and 8B are graphs showing measured EMI noises of a plasma display device according to an exemplary embodiment. FIG. 8A shows the EMI noise measured by the plasma display device (before working) having no conductive gasket 500, and FIG. 8B shows the EMI noise measured by the plasma display device (after working) having the conductive gasket 500.

Comparing graphs in FIGS. 8A and 8B, it can be understood that in a region below 100 MHz that has a great effect on the infrared signal reception, the regions 800 and 810 having a considerably high level before working do not appear at all. Through this, it can be understood that the EMI noise is considerably reduced in the plasma display device having the conductive gasket 500 according to an exemplary embodiment.

In summary, in the case of physically connecting the driving circuit portion 300 to the base chassis 200 and/or panel 100 through the conductive gasket 500, it becomes possible to adjust the flow of high current in the driving circuit portion 300, and thus a technical effect that can attenuate the EMI noise can be achieved.

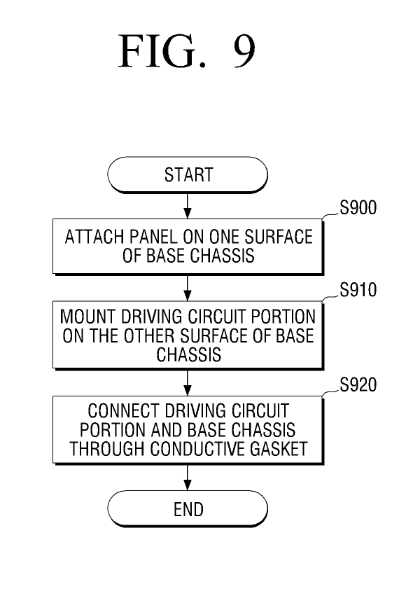

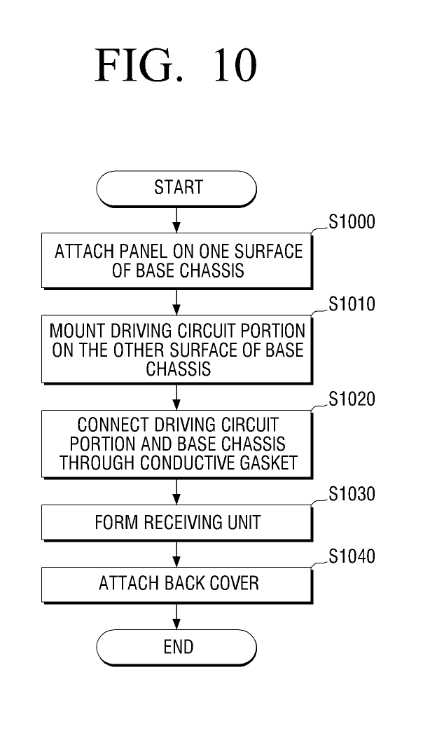

Hereinafter, a method of manufacturing a plasma display device according to an exemplary embodiment will be described with reference to FIGS. 9 and 10.

FIG. 9 is a flowchart illustrating a method of manufacturing a plasma display device according to an embodiment of the present invention.

A panel 100 is attached to one surface of the base chassis 200 (S900). Then, a driving circuit portion 300 is mounted on the other surface of the base chassis 200 (S910). Last, the driving circuit portion 300 and the base chassis 200 are physically connected and fixed by the conductive gasket 500 (S920).

On the other hand, it is also possible to physically connect and fix the driving circuit 310 to the base chassis 200 using the conductive gasket 500 or to prepare the conductive gasket 500 on the upper/lower edge portion of the base chassis 200.

FIG. 10 is a flowchart illustrating a method of manufacturing a plasma display device according to another exemplary embodiment. In the same manner as in FIG. 9, a panel 100 is attached to one surface of the base chassis 200 (S1000), and a driving circuit portion 300 is mounted on the other surface of the base chassis 200 (S1010). Also, the panel 100, the base chassis 200, and the driving circuit portion 300 are physically connected and fixed by the conductive gasket 500 (S1020).

Thereafter, a receiving unit for receiving an infrared signal from the outside is formed (S1030), and a back cover is finally attached to complete the plasma display device (S1040).

FIG. 10 merely illustrates the main technical feature of the plasma display device according to an exemplary embodiment, and steps of forming a power supply unit 410, a control unit 420, and an address driving circuit portion 400 may be further included. Also, the order according to the flow illustrated in FIG. 10 may not be adopted. That is, the plasma display device can be completed by laminating the units that can be included in diverse orders.

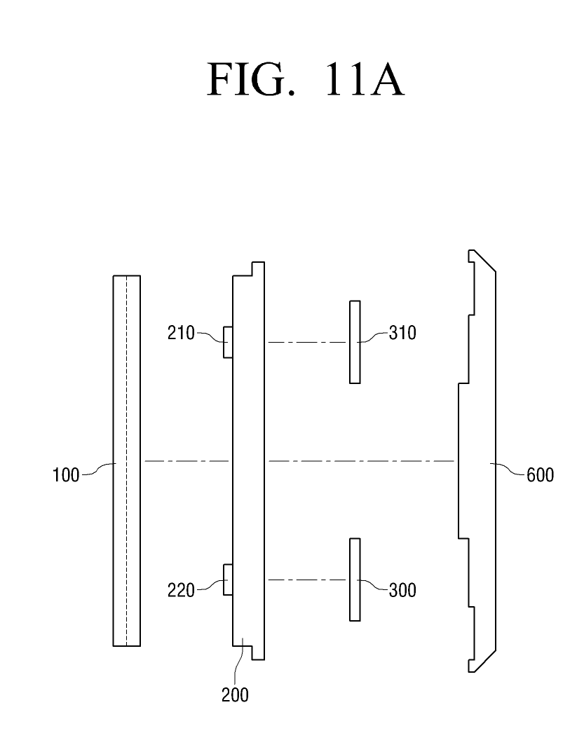

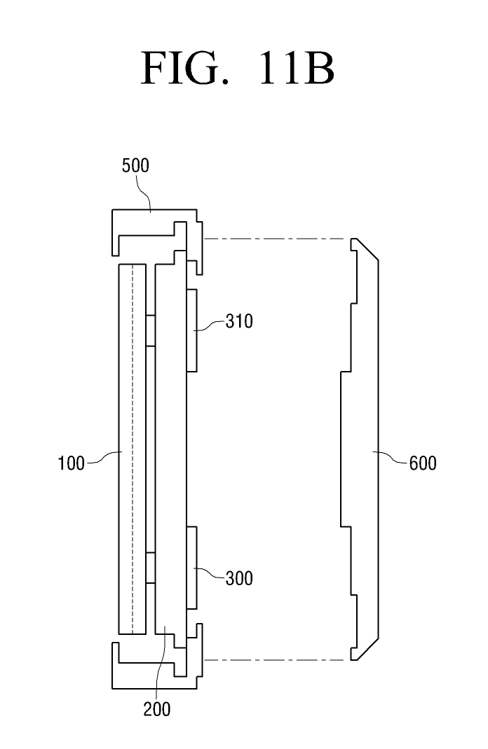

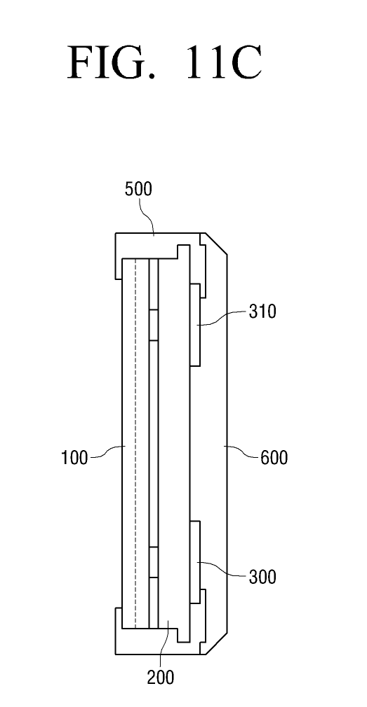

FIGS. 11A to 11C are views illustrating the configuration of a plasma display device explaining a method of manufacturing the plasma display device according to an exemplary embodiment.

A panel 100 is attached to one surface of the base chassis 200. Particularly, gaskets 210 and 220 may be further included between them to further attenuate the EMI. That is, the EMI radiation noise can be reduced in the case where the panel 100 is connected to the base chassis 200 through the gaskets 210 and 220 rather than the panel 100 being directly connected to the base chassis 200.

On the other surface of the base chassis 200, the X-driving circuit portion 310 and the Y-driving circuit portion 300 are mounted. Thereafter, the conductive gasket 500 is further included (FIGS. 11B and 11C). This conductive gasket 500 may be configured to surround the panel 100, the base chassis 200, and the driving circuit portions 300 and 310. On the other hand, unlike FIGS. 11B and 11C, the conductive gasket 500 may be provided only on the edge portion on one side as described above.

Last, a back cover 600 is attached to complete the plasma display device. As described above, it could be understood by a person of ordinary skill in the art that most configurations included in the plasma display device are omitted. That is, diverse units such as the address driving circuit portion 400, the power supply unit 410, the control unit 420, the receiving unit, and the like, which may be included in the plasma display device are omitted. By these diverse methods, the units may be arranged in diverse forms in the plasma display device.

According to diverse embodiments of the present invention as described above, the EMI that is emitted from the driving circuit portion can be shielded, and thus the performance of the plasma display device can be improved. Also, a thinner plasma display device can be provided with the shielding of the EMI.

While the invention has been shown and described with reference to certain embodiments thereof, it will be understood by those skilled in the art that various changes in form and detail may be made therein without departing from the spirit and scope of the invention, as defined by the appended claims.

What is claimed is:

1. A plasma display device comprising:
a panel;
a driving circuit portion driving the panel;
a base chassis on which the driving circuit portion is mounted; and
a conductive gasket physically connecting the driving circuit portion to the base chassis.

2. The plasma display device as claimed in claim 1, wherein the conductive gasket physically connects and fixes the driving circuit portion to edge portions of the base chassis.

3. The plasma display device as claimed in claim 2, wherein the conductive gasket physically connects and fixes the driving circuit portion to edge portions of the panel together with the edge portions of the base chassis.

4. The plasma display device as claimed in claim 3, wherein the conductive gasket fixes and physically connects only edge portions of a structure in which the panel, the base chassis, and the driving circuit portion is laminated in the form of surrounding the edge portions.

5. The plasma display device as claimed in claim 1, wherein the conductive gasket physically connects at least one edge portion of upper, lower, left, and right edge portions of the base chassis.

6. The plasma display device as claimed in claim 1, further comprising a receiving unit wirelessly receiving an external signal;
wherein the external signal is an IR signal or an RF signal output from a remote controller.

7. The plasma display device as claimed in claim 1, further comprising a back cover shielding the base chassis, the driving circuit portion, and a plurality of units connected to the driving circuit portion.

8. A method of manufacturing a plasma display device comprising:
attaching a panel to one surface of a base chassis;
mounting a driving circuit portion driving the panel on an other surface of the base chassis; and
physically connecting the driving circuit portion to the base chassis through a conductive gasket.

9. The method as claimed in claim 8, wherein the connection step physically connects and fixes the driving circuit portion to edge portions of the base chassis through the conductive gasket.

10. The method as claimed in claim 9, wherein the connection step physically connects and fixes the driving circuit portion to edge portions of the panel together with the edge portions of the base chassis through the conductive gasket.

11. The method as claimed in claim 10, wherein the connection step fixes and physically connects only edge portions of a structure in which the panel, the base chassis, and the driving circuit portion are laminated in the form of surrounding the edge portions through the conductive gasket.

12. The method as claimed in claim 8, wherein the connection step physically connects at least one edge portion of upper, lower, left, and right edge portions of the base chassis through the conductive gasket.

13. The method as claimed in claim 8, further comprising forming a receiving unit wirelessly receiving an external signal;
wherein the external signal is an IR signal or an RF signal output from a remote controller.

14. The method as claimed in claim 8, further comprising attaching a back cover shielding the base chassis, the driving circuit portion, and a plurality of units connected to the driving circuit portion.
